(19) United States
(12) Patent Application Publication
(10) Pub. No.: US 2004/0020600 A1
(43) Pub. Date: Feb. 5, 2004

(54) Semiconductor device manufacturing equipment having gate providing multiple seals between adjacent chambers

(76) Inventor: Sang-Hag Lee, Seoul (KR)

Correspondence Address: VOLENTINE FRANCOS, P.L.L.C., Suite 150, 12200 Sunrise Valley Drive, Reston, VA, 20191, US

(21) Appl. No.: 10/600,356

(22) Filed: Jun. 23, 2003

(30) Foreign Application Priority Data
Aug. 5, 2002 (KR) 2002-46153

(51) Int. Cl. H01L 21/306

(52) U.S. Cl. 156/345.32

(57) ABSTRACT

Semiconductor device manufacturing equipment having multiple chambers, including at least one process chamber, provides multiple seals between the chambers so that a semiconductor manufacturing process can continue even when a leak occurs at one of the seals. In addition to the process chamber(s), the semiconductor manufacturing equipment includes a load-lock chamber, a transfer chamber having a robot by which a wafer in the load-lock chamber is transferred to a process chamber, a respective gate by which the chambers of each adjacent pair are connected, and a gate valve disposed in each gate. The gate defines a plurality of doorways leading into the adjoining chambers. The gate valve has a plurality of doors that can be concurrently positioned over the doorways, respectively, to establish a plurality of seals between one chamber and the chamber connected thereto by the gate.

### BACKGROUND OF THE INVENTION

1. Field of the Invention

The present invention relates to semiconductor device manufacturing equipment. More particularly, the present invention relates to semiconductor device manufacturing equipment having a plurality of chambers including at least one processing chamber, and a gate(s) through which semiconductor wafers are transferred between the chambers.

2. Description of the Related Art

A semiconductor device is usually manufactured by forming two or more thin film layers on a pure silicon wafer, and patterning the layers to form a desired circuit pattern. To this end, the manufacturing process generally comprises repeatedly performing a plurality of unit processes such as photolithographic, etching and thin film deposition processes and the like. Moreover, most of these unit processes must be performed in a high vacuum atmosphere to work very precisely.

More specifically, most of the unit processes used in the manufacturing of semiconductor devices must be carried out under a predetermined pressure, for example, a low pressure or a high pressure, if the process is to produce the desired results. In order to accomplish the above, the semiconductor manufacturing equipment for performing each of the unit processes comprises a vacuum exhaust device, such as a turbo pump, for maintaining each of several chambers at the desired pressure, and a gate valve for selectively sealing a gate through which the wafer is transferred between the chambers.

More specifically, conventional dry etching equipment for etching a wafer comprises: a process chamber in which the wafer is etched, a load-lock chamber in which a pre-processed wafer is temporarily maintained before the wafer is transferred to the process chamber, a transfer chamber through which the wafer is transferred from the load-lock chamber to the process chamber, a vacuum exhaust device for evacuating each of the chambers, a gate through which the wafer passes from one chamber to another, and a gate valve that selectively seals each gate to maintain the desired pressure in each chamber.

Accordingly, the vacuum exhaust device associated with each of the process chambers pumps up air from the inside of the chamber to maintain the chamber at the pressure desired for carrying out the process. The gate valve installed on each gate selectively seals the gate once the wafer has been transferred therethrough into the process chamber so that the wafer can be precisely processed. That is, the gate valve serves to maintain a normal pressure condition in the chamber.

However, according to the conventional semiconductor manufacturing equipment, the gate valve seals only one side of the gate. Therefore, the normal pressure at which the manufacturing process is carried out can not be maintained in the process chamber when a leak occurs at the sealed side of the gate. In this case, the manufacturing equipment is not able to implement the conditions required for processing the wafer precisely.

### SUMMARY OF THE INVENTION

An object of the present invention is to solve the above-described problems of the prior art. More specifically, an object of the present invention is to provide semiconductor manufacturing equipment that provides multiple discrete seals between adjacent ones of interconnected chambers of the equipment so that the equipment may continue to operate effectively even when a leak occurs at one of the seals. Preferably, one of the chambers is a process chamber in which a semiconductor manufacturing process is carried out.

According to one aspect of the present invention, the semiconductor manufacturing equipment, comprises a plurality of chambers including a load-lock chamber and at least one process chamber in which a process environment must be produced to process semiconductor wafers, a gate open between and connecting a pair of the chambers, and a gate valve disposed in the gate and providing the multiple seals between the connected chambers. The equipment is preferably multi-chamber processing equipment including a transfer chamber having a robot by which the wafers are transferred from the load-lock chamber to a process chamber.

The gate defines a first doorway and a second doorway by which a wafer is admitted into or out of each of the chambers connected to one another by the gate. The gate valve comprises a first door for closing the first doorway, a second door for closing the second doorway, and a drive mechanism for opening and closing the first and the second doors over the first and second doorways, respectively. The driving mechanism preferably includes a fluid-actuated cylinder such as a pneumatic cylinder that is operated by compressed air.

### BRIEF DESCRIPTION OF THE DRAWINGS

These and other objects, features and advantages of the present invention will be more apparent from the following detailed description thereof made in conjunction with the accompanying drawings, in which like reference numerals designate like elements, and in which:

FIG. 1 is a schematic diagram of semiconductor device manufacturing equipment according to the present invention;

FIG. 2 is a perspective view of part of a gate of the semiconductor device manufacturing equipment as taken in the direction of line A-A in FIG. 1; and

FIG. 3 is a similar perspective view the gate but sealed by the gate valve.

### DETAILED DESCRIPTION OF PREFERRED EMBODIMENTS

The semiconductor device manufacturing equipment according to the embodiment of the present invention will now be described with reference to the accompanying drawings.

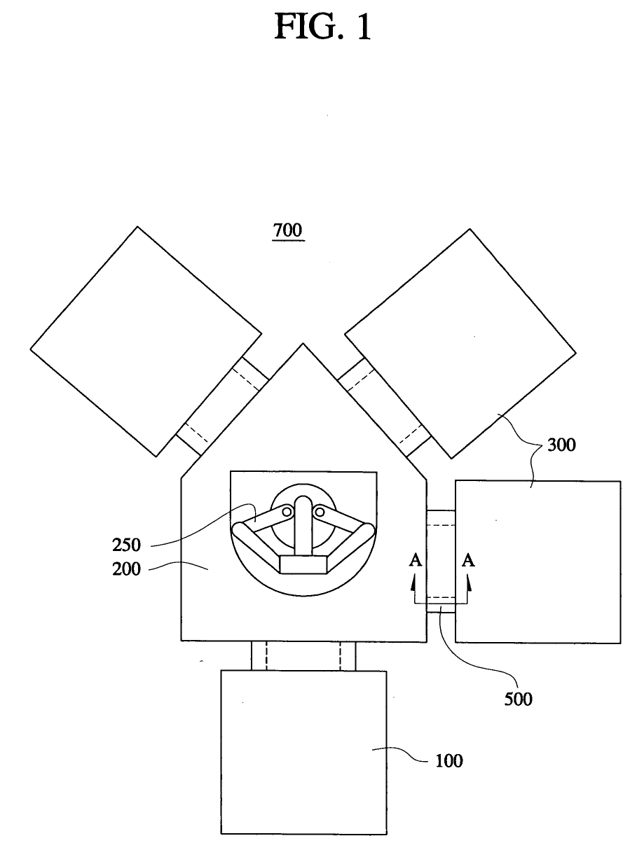

Referring first to FIG. 1, the semiconductor device manufacturing equipment 700 comprises a load-lock chamber 100 into which a pre-processed wafer (not shown) is transferred, at least one process chamber 300 for processing wafers, such as etching or forming a thin film on the wafers, a transfer chamber 200 through which a wafer in the load-lock chamber 100 is transferred to a process chamber 300, gates 500 connecting adjacent ones of the chambers 100, 200 and 300 and defining respective openings through which a wafer can pass between the chambers, and a central control device (not shown). Furthermore, the equipment 700 preferably comprises a plurality of the process chambers 300 so that the wafers of the load-lock chamber 100 can be simultaneously processed.

Each process chamber 300 comprises a vessel, a heater (not shown) for heating the interior of the process chamber 300 to a desired temperature, e.g., that at which an etching process or a thin film deposition process is performed, a vacuum exhaust device (not shown) for maintaining the interior of the process chamber 300 at a desired pressure, and a system (not shown) for supplying a reaction gas into the vessel.

A central control device (not shown) is also provided for controlling the various elements of the equipment 700. For instance, the central control device establishes a desired process environment within the vessel of the process chamber 300 by controlling the system by which the reaction gas is allowed to flow into the chamber 300, a radio frequency power by which the reaction gas is excited, and the vacuum exhaust device by which gas is evacuated from the chamber 300.

On the other hand, the load-lock chamber 100 comprises a vessel, a wafer cassette (not shown) configured to store a number of pre-processed wafers in a certain alignment such that they can be withdrawn and processed sequentially, and a vacuum exhaust device (not shown) to maintain the interior of the Vessel of the chamber 100 under a desired of pressure, thereby preventing an inflow of particles from the outside.

The transfer chamber 200 is located between the load-lock chamber 100 and the plurality of the process chamber 300. The transfer chamber 200 includes a robot 250 for transferring the wafers between the chambers 100, 200 and 300 according to the sequence of the particular manufacturing process carried out by the equipment 700. For instance, the robot 250 rapidly loads and unloads the wafers from the load-lock chamber 100 into each of the process chamber 300 and returns the wafers once processed from a process chamber 300 into the load-lock chamber 100.

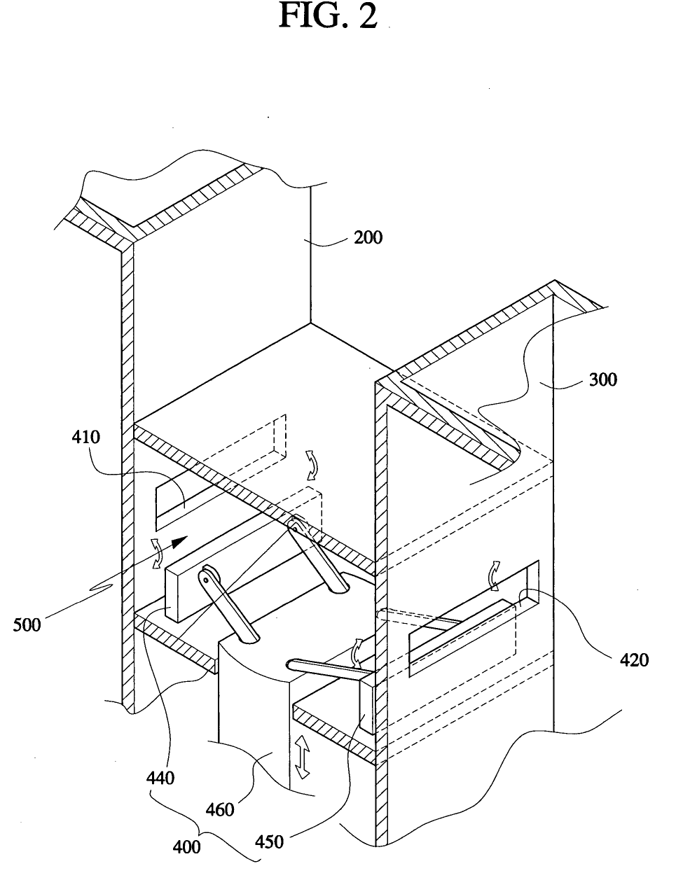

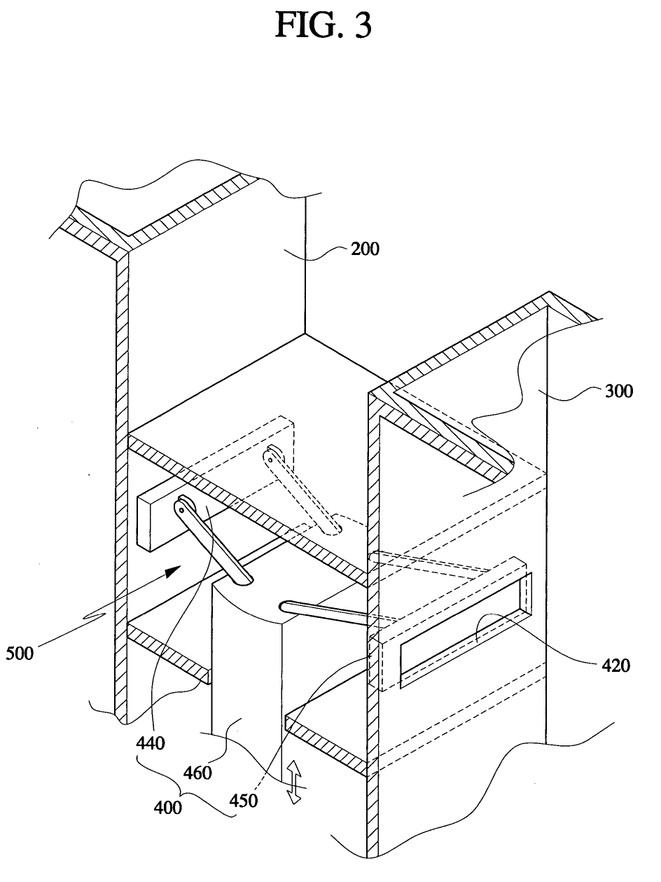

Referring now to FIGS. 1-3, the gates 500 define respective passageways interconnecting the chambers 100, 200 and 300 so that a wafer may be transferred among the chambers 100, 200 and 300. A gate valve 400 is operable to selectively seal the gate 500 and hence, to provide a seal between the chambers 100, 200 and 300 interconnected by the gate 500, whereby the desired pressures can be maintained in the chambers 100, 200 and 300. The gate 500 and the gate valve 400 located between the transfer chamber 200 and the process chamber 300 will now be described in more detail with reference to FIGS. 2 and 3.

The gate 500 forms a first doorway 410 and a second doorway 420 having a size capable of allowing the robot 250 to pass therethrough and thereby load the wafers into the process chamber 300 from the transfer chamber 200. The gate valve 400 hermetically seals the gate 500 by forming pressure seals around both doorways 410 and 420, i.e., at both sides of the gate 500. The pressure seals are created by, for example, O-rings of the doors 440, 450 that extend around the doorways 410, 420 when the doors 440, 450 are closed over the doorways 410, 420. The gate valve 400 is thus capable of maintaining the pressure within each of the adjoining chambers 200, 300.

To this end, the gate valve 400 comprises a first door 440 for directly closing the first doorway 410 to seal it, a second door 450 for directly closing the second doorway 420 to seal it, and a drive unit 460 comprising a pneumatic cylinder operable to move the first door 440 and the second door 450 over the first doorway 410 and the second doorway 420, respectively.

The operation and effects of the semiconductor manufacturing equipment 700 according the present invention will now be described in more detail.

Firstly, pre-processed wafers are transferred to the load-lock chamber 100. At this time, the vacuum exhaust system maintains predetermined pressure levels in the load-lock chamber 100, the transfer chamber 200, and the process chamber 300. In particular, the process chamber 300 is heated and maintained at the pressure at which the wafer is to be processed therein.

Next, the pressure in the load-lock chamber 100 is brought up to the level of the pressure in process chambers 300. The drive units 460 of gate valves 400 interconnecting the load-lock chamber 100 and the process chambers 300 then manipulate the first doors 440 and the second doors 450 to open the respective doorways 410, 420 constituting the passageway that connects the chambers 100 and 300. Subsequently, the robot 250 transfers a respective wafer from the load-lock chamber 100 to each process chamber 300 according to a prescribed sequence of operations.

After the wafers have been transferred to the process chambers 300, the gate valves 400 operate to seal the first doorways 410 and the second doorways 420, i.e., provide multiple seals for each gate 500. Accordingly, the pressure in each process chamber 300 is maintained so that the process, such as the etching process or thin film deposition process, can be carried out with a high degree of precision within the chamber 300.

Accordingly, even if a leak occurs at one doorway due to a defect in an O-ring of the door used to seal the doorway, the other doorway is sealed by the other door. As a result, the pressure level in the process chamber 300 is maintained at a level at which the wafer can be processed satisfactorily in spite of the leak.

As described above, the semiconductor manufacturing equipment 700 of the present invention provides multiple seals for each gate 500 that interconnects a pair of chambers, e.g., provides seals at both sides of the gate 500, respectively. Accordingly, the processing of the wafers is allowed to proceed without interruption even when a leak is present at one side of the gate 500.

Finally, although the present invention has been particularly shown and described with reference to the preferred embodiment thereof, the present invention is not so limited. For instance, the present invention is not only limited to the dual-actuated type of gate valve shown and described. Rather, any valve structure that is capable of sealing the doorways of the gate can be used. Therefore, these and other changes in form and details may be made to the preferred embodiments without departing from the true spirit and scope of the invention as defined by the appended claims.

What is claimed is:

1. Semiconductor device manufacturing equipment, comprising:
a plurality of interconnected chambers including a load-lock chamber, and at least one process chamber in which a wafer is to be processed;
a gate interposed between a pair of adjacent ones of said chambers and by which the chambers of said pair are connected, said gate constituting an open passageway along which a wafer is transferred between the chambers of said pair, and said gate defining doorways that each lead into a respective one of the chambers of said pair, the doorways each being sized to admit a semiconductor wafer therethrough; and
a gate valve disposed in said gate, said gate valve comprising a plurality of doors, and a driving unit operative to concurrently position said doors over said doorways, respectively, and thereby establish a plurality of discrete seals between the pair of chambers connected by the gate.

2. The semiconductor device manufacturing equipment according to claim 1, wherein said driving unit comprises a fluid-actuated cylinder connected to each of said doors.

3. The semiconductor device manufacturing equipment according to claim 1, wherein said gate adjoins said process chamber.

4. The semiconductor device manufacturing equipment according to claim 1, wherein said plurality of chambers include a transfer chamber interposed between said load-lock chamber and said at least one process chamber, said transfer chamber having an internal space constituting said passageway, and comprising a robot operative to transfer a wafer along said passageway from said load-lock chamber to said at least one process chamber.

5. The semiconductor device manufacturing equipment according to claim 4, wherein said gate adjoins said transfer chamber and one of said process chambers.
